(19) United States
(12) Patent Application Publication
(10) Pub. No.: US 2021/0273076 A1
(43) Pub. Date: Sep. 2, 2021

(54) METHOD OF FORMING GATE

(71) Applicant: UNITED MICROELECTRONICS CORP., Hsin-Chu City (TW)

(72) Inventors: Yang-Ju Lu, Changhua County (TW); Chun-Yi Wang, Changhua County (TW); Fu-Shou Tsai, Keelung City (TW); Yong-Yi Lin, Miaoli County (TW); Ching-Yang Chuang, Pingtung County (TW); Wen-Chin Lin, Tainan City (TW); Hsin-Kuo Hsu, Kaohsiung City (TW)

(21) Appl. No.: 16/802,564

(22) Filed: Feb. 27, 2020

(51) Int. Cl. H01L 29/66; H01L 21/3105; H01L 21/02

(52) U.S. Cl. CPC H01L 29/66545; H01L 21/31053; H01L 21/0217; H01L 21/02252; H01L 21/02236; H01L 21/0228; H01L 21/0214

(57) ABSTRACT

A method of forming a gate includes the following steps. A gate structure is formed on a substrate. An etch stop layer is formed on the gate structure and the substrate. A dielectric layer is formed to cover the etch stop layer. The dielectric layer is planarized to form a planarized top surface of the dielectric layer and expose a portion of the etch stop layer on the gate structure. An oxygen containing treatment is performed to form an oxygen containing layer on the exposed etch stop layer. A deposition process is performed to form an oxide layer covering the planarized top surface of the dielectric layer and the oxygen containing layer.

### BACKGROUND OF THE INVENTION

### 1. Field of the Invention

The present invention relates generally to a method of forming a gate, and more specifically to a method of forming a gate through performing an etching or polishing process.

### 2. Description of the Prior Art

In the semiconductor industry, chemical mechanical polishing (CMP) is the most common and important planarization tool applied. For example, the CMP process can be used to remove a topographical target of a thin film layer on a semiconductor wafer. The CMP process produces a wafer with both a regular and planar surface, to ensure a depth of focus (DOF) in the following photo process. Certain complications are involved in the CMP process, including the property of the target thin film layer, uniformity of the target thin film surface, composition and pH value of the slurry, composition of the polishing pad, platen rotational speed, head down force, etc. For example, as an area of the target thin film has a wide or isolated part, loading effect would occur and lead to divots at the target thin film surface after CMP process. Or, scratching occurs and leads to voids at a top surface of a layer after CMP process. As a result, this rough target thin film surface would degrade the performance and the reliability of devices.

### SUMMARY OF THE INVENTION

The present invention provides a method of forming a gate, which forms a dielectric layer having a flat top surface by processing an oxygen containing treatment before depositing an oxide layer on the dielectric layer. Hence, the dielectric layer has a flat top surface after planarizing the oxide layer and the oxygen containing treatment.

The present invention provides a method of forming a gate including the following steps. A gate structure is formed on a substrate. An etch stop layer is formed on the gate structure and the substrate. A dielectric layer is formed to cover the etch stop layer. The dielectric layer is planarized to form a planarized top surface of the dielectric layer and expose a portion of the etch stop layer on the gate structure. An oxygen containing treatment is performed to form an oxygen containing layer on the exposed etch stop layer. A deposition process is performed to form an oxide layer covering the planarized top surface of the dielectric layer and the oxygen containing layer.

According to the above, the present invention provides a method of forming a gate, which forms a gate structure on a substrate, forms an etch stop layer on the gate structure and the substrate, forms a dielectric layer covering the etch stop layer, planarizes the dielectric layer to form a planarized top surface of the dielectric layer and expose a portion of the etch stop layer on the gate structure, wherein voids are at the planarized top surface of the dielectric layer due to scratching while planarizing. Then, an oxygen containing treatment is performed to form an oxygen containing layer on the exposed etch stop layer, and a deposition process is performed to form an oxide layer covering the planarized top surface of the dielectric layer and the oxygen containing layer, thereby the oxide layer can have a flatter top surface due to the oxygen containing layer being formed. Therefore, after the oxide layer and the oxygen containing layer are planarized until the dielectric layer being exposed, the dielectric layer can have a flat top surface.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 schematically depicts a cross-sectional view of a method of forming a gate according to an embodiment of the present invention.

FIG. 2 schematically depicts a cross-sectional view of a method of forming a gate according to an embodiment of the present invention.

FIG. 3 schematically depicts a cross-sectional view of a method of forming a gate according to an embodiment of the present invention.

FIG. 4 schematically depicts a cross-sectional view of a method of forming a gate according to an embodiment of the present invention.

FIG. 5 schematically depicts a cross-sectional view of a method of forming a gate according to an embodiment of the present invention.

FIG. 6 schematically depicts a cross-sectional view of a method of forming a gate according to an embodiment of the present invention.

FIG. 7 schematically depicts a cross-sectional view of a method of forming a gate according to an embodiment of the present invention.

FIG. 8 schematically depicts a cross-sectional view of a method of forming a gate according to an embodiment of the present invention.

### DETAILED DESCRIPTION

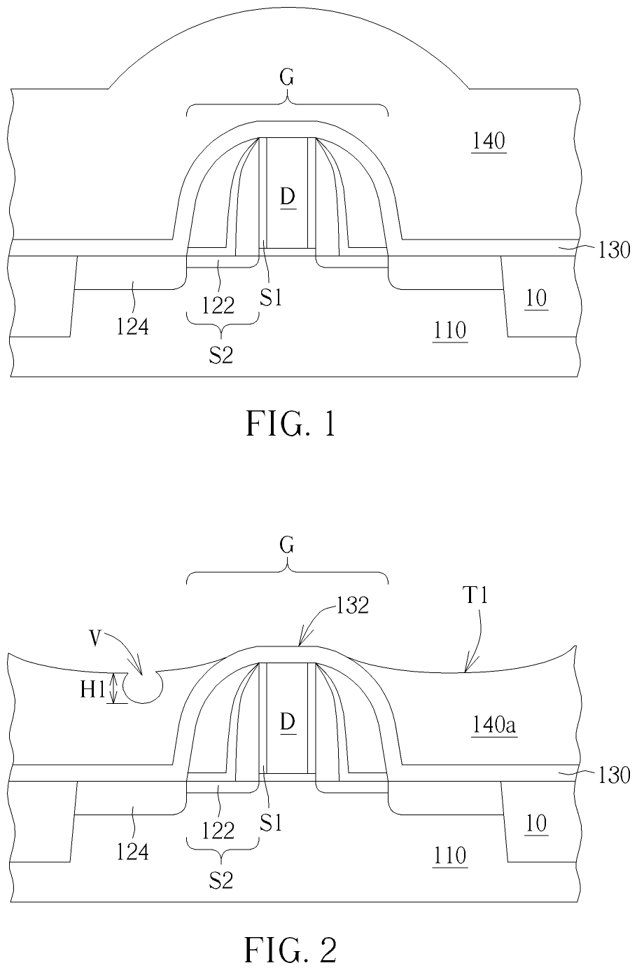

FIGS. 1-8 schematically depict cross-sectional views of a method of forming a gate according to an embodiment of the present invention. A substrate 110 is provided. The substrate 110 may be a semiconductor substrate such as a silicon substrate, a silicon containing substrate, a III-V group-on-silicon (such as GaN-on-silicon) substrate, a graphene-on-silicon substrate, a silicon-on-insulator (SOI) substrate or a substrate containing epitaxial layers. Isolation structures 10 are formed in the substrate 110 to electrically isolate each transistor. The isolation structures 10 may be shallow trench isolation (STI) structures, which may be formed by a shallow trench isolation process, and the forming method is known in the art, and will not be described herein, but it is not limited thereto. A gate structure G is formed on the substrate 110. Methods of forming the gate structure G may include the following. A dummy gate D is formed on the substrate 110 and spacers S1/S2 may be formed on the substrate 110 beside the dummy gate D. In this embodiment, a first spacer S1 may be formed on the substrate 110 beside the dummy gate D, and a lightly doped source/drain region 122 is formed in the substrate 110 next to the first spacer S1. Then, a second spacer S2 may be formed on the substrate 110 beside the first spacer S1, and a source/drain region 124 is formed in the substrate 110 next to the second spacer S2. The second spacer S2 may be one single spacer or a multilayer spacer, depending upon requirements. In this case, the second spacer S2 is a triple spacer, which can adjust the distance between the source/drain region 124 and the dummy gate D.

An etch stop layer 130 covers the gate structure G and the substrate 110. In this embodiment, the etch stop layer 130 may be a silicon nitride layer, but it is not limited thereto.

A dielectric layer 140 is deposited to cover the etch stop layer 130. The dielectric layer 140 may be deposited by an undoped silicate glass (USG) process or a high density plasma chemical vapor deposition (HDP-CVD) process etc.

Then, the dielectric layer 140 is planarized to form a dielectric layer 140a having a planarized top surface Tl and expose a portion 132 of the etch stop layer 130 on the gate structure G, as shown in FIG. 2. The dielectric layer 140 is scratched while planarizing, and thus the formed dielectric layer 140a has voids v at the planarized top surface T1. Heights H1 of the voids v may be 100-200 angstroms, but it is not limited thereto. These voids v would lead to performance degrading caused by metal (such as work function metal, aluminum (Al) or copper (Cu)) residue in these voids in later metal gate filling process, and short circuits may occur.

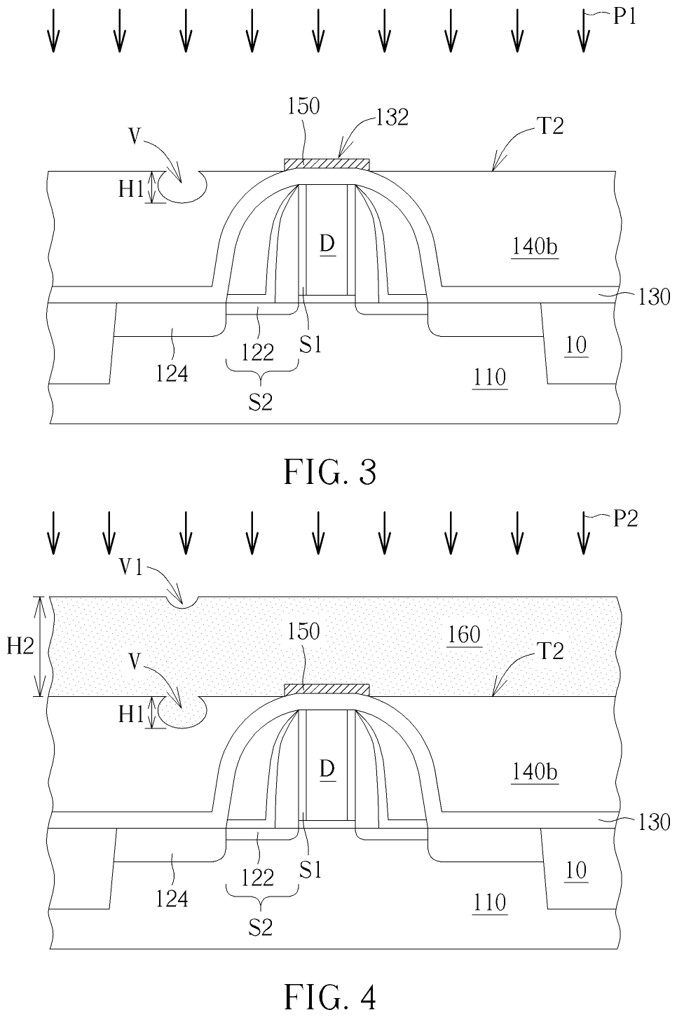

As shown in FIG. 3, an oxygen containing treatment P1 is performed to form an oxygen containing layer 150 on the portion 132 of the etch stop layer 130 and a dielectric layer 140b having a planarized top surface T2. The planarized top surface T2 of the dielectric layer 140b is flatter than the planarized top surface T1 of the dielectric layer 140a due to the oxygen containing treatment Pl. Since the etch stop layer 130 is a silicon nitride layer, the oxygen containing layer 150 includes a silicon oxynitride layer. Preferably, the oxygen containing treatment P1 includes an O₂ treatment or an oxygen plasma treatment, but it is not limited thereto.

As shown in FIG. 4, a deposition process P2 is performed to form an oxide layer 160 covering the planarized top surface T2 of the dielectric layer 140b and the oxygen containing layer 150. Since the oxygen containing treatment P1 is performed to form the oxygen containing layer 150 on the portion 132 of the etch stop layer 130, the oxide layer 160 could have a flatter top surface. A height H2 of the oxide layer 160 is larger than the heights H1 of the voids v for filling up these voids v. Thus, the height H1 of the oxide layer 160 may be 300-500 angstrom. Preferably, the deposition process P2 includes an atomic layer deposition (ALD) process to control the height H2 precisely, but it is not limited thereto. The oxide layer 160 may still have voids v1, but the voids v1 of the oxide layer 160 are smaller than the voids v of the planarized top surface T2 of the dielectric layer 140b.

Thereafter, a planarization process P3 is performed to planarize the oxide layer 160 and the oxygen containing layer 150 until an etch stop layer 130a and a dielectric layer 140c having a flat top surface T3 being exposed. The voids v of the dielectric layer 140a as shown in FIG. 2 are eliminated, and the dielectric layer 140c having a flat top surface T3 is carried out. Methods of planarizing the oxide layer 160 and the oxygen containing layer 150 may include performing an etching process or a polishing process. The etching process may include a dry etching process, a wet etching process, or a previous dry etching process and then a wet etching process. The polishing process may include a chemical mechanical polishing (CMP) process, but it is not limited thereto. The etching rate of the etching process to the etch stop layer 130a, the oxygen containing layer 150 and the oxide layer 160 is the same, to form the flat top surface T3 constituted by a top surface T31 of the etch stop layer 130a and a top surface T32 of the dielectric layer 140c. Likewise, the etching rate of the polishing process to the etch stop layer 130a, the oxygen containing layer 150 and the oxide layer 160 is the same, to form the flat top surface T3 constituted by the top surface T31 of the etch stop layer 130a and the top surface T32 of the dielectric layer 140c.

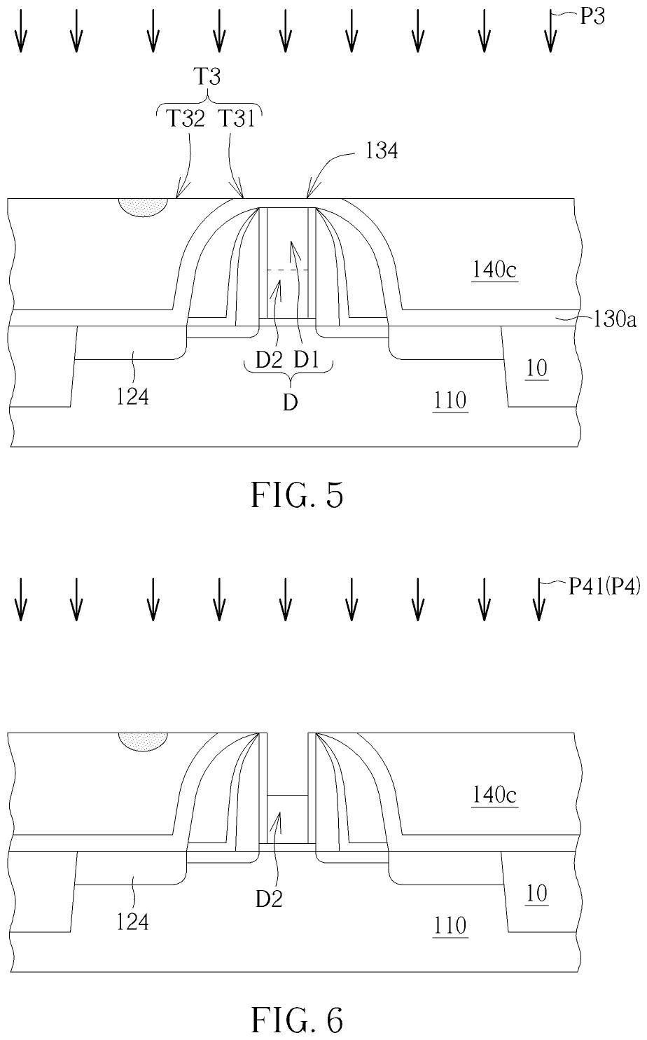

Then, a removing process P4 is performed to remove a part 134 of the etch stop layer 130a right above the dummy gate D and the dummy gate D for forming a metal gate, as shown in FIGS. 5-7. In this embodiment, the removing process P4 includes a first removing process P41 and a second removing process P42. More precisely, as shown in FIGS. 5-6, the first removing process P41 is performed to remove the part 134 of the etch stop layer 130a right above the dummy gate D and a top part Dl of the dummy gate D. The first removing process P41 is preferably a dry etching process, but it is not limited thereto. In one embodiment, the first removing process P41 may include a dry etching process for removing the part 134 of the etch stop layer 130a right above the dummy gate D, and then a dry etching process for removing the top part Dl of the dummy gate D.

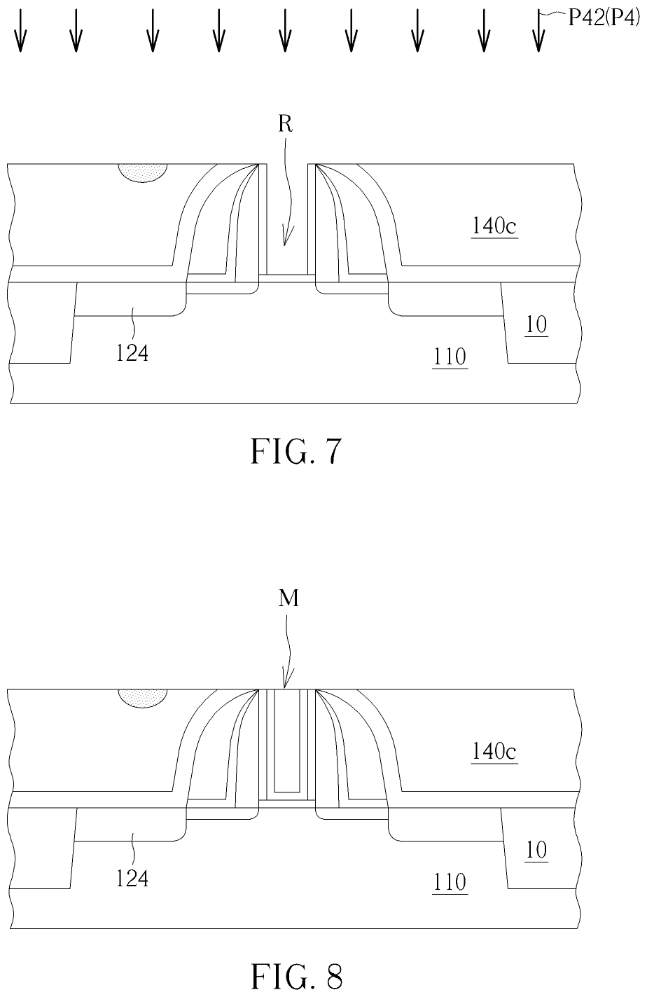

Then, as shown in FIGS. 6-7, the second removing process P42 is performed to remove a remaining part D2 of the dummy gate D, thereby forming a recess R in the dielectric layer 140c. The second removing process P42 may include a wet etching process for only removing the remaining part D2 of the dummy gate D. Then, as shown in FIGS. 7-8, a metal gate M is formed in the recess R.

To summarize, the present invention provides a method of forming a gate, which forms a gate structure on a substrate, forms an etch stop layer on the gate structure and the substrate, forms a dielectric layer covering the etch stop layer, planarizes the dielectric layer to form a planarized top surface of the dielectric layer and expose a portion of the etch stop layer on the gate structure, wherein voids are at the planarized top surface of the dielectric layer due to scratching while planarizing. Then, an oxygen containing treatment is performed to form an oxygen containing layer on the exposed etch stop layer, and a deposition process is performed to form an oxide layer covering the planarized top surface of the dielectric layer and the oxygen containing layer, thereby the oxide layer can have a flatter top surface due to the oxygen containing layer being formed. Therefore, after the oxide layer and the oxygen containing layer are planarized until the dielectric layer being exposed, the dielectric layer can have a flat top surface.

Moreover, the oxygen containing treatment may include an 0₂ treatment or an oxygen plasma treatment, and the deposition process may include an atomic layer deposition (ALD) process, to control the thickness of the formed oxide layer precisely. Methods of planarizing the oxide layer and the oxygen containing layer preferably include performing an etching process or a polishing process. The etching rate of the etching process/the etching rate of the polishing process to the etch stop layer, the oxygen containing layer and the oxide layer is the same, so that a flat top surface constituted by a top surface of the etch stop layer and a top surface of the dielectric layer can be formed.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A method of forming a gate, comprising:
forming a gate structure on a substrate;
forming an etch stop layer on the gate structure and the substrate;
forming a dielectric layer covering the etch stop layer;
planarizing the dielectric layer to form a planarized top surface of the dielectric layer and expose a portion of the etch stop layer on the gate structure;
performing an oxygen containing treatment to form an oxygen containing layer on the exposed etch stop layer; and
performing a deposition process to form an oxide layer covering the planarized top surface of the dielectric layer and the oxygen containing layer.

2. The method of forming a gate according to claim 1, further comprising:
planarizing the oxide layer and the oxygen containing layer until the dielectric layer being exposed.

3. The method of forming a gate according to claim 1, wherein the etch stop layer comprises a silicon nitride layer.

4. The method of forming a gate according to claim 3, wherein the oxygen containing layer comprises a silicon oxynitride layer.

5. The method of forming a gate according to claim 1, wherein the oxygen containing treatment comprises an 0₂ treatment or an oxygen plasma treatment.

6. The method of forming a gate according to claim 1, wherein the deposition process comprises an atomic layer deposition (ALD) process.

7. The method of forming a gate according to claim 1, wherein the planarized top surface of the dielectric layer and the oxide layer have voids, and the voids of the oxide layer are smaller than the voids of the planarized top surface of the dielectric layer.

8. The method of forming a gate according to claim 2, wherein methods of planarizing the oxide layer and the oxygen containing layer comprise performing an etching process or a polishing process.

9. The method of forming a gate according to claim 8, wherein the etching process comprises a dry etching process or a wet etching process.

10. The method of forming a gate according to claim 8, wherein the polishing process comprises a chemical mechanical polishing (CMP) process.

11. The method of forming a gate according to claim 8, wherein the etching rate of the etching process to the etch stop layer, the oxygen containing layer and the oxide layer is the same.

12. The method of forming a gate according to claim 8, wherein the etching rate of the polishing process to the etch stop layer, the oxygen containing layer and the oxide layer is the same.

13. The method of forming a gate according to claim 2, wherein the gate structure comprises a dummy gate, and a method of forming the gate structure further comprises:
performing a removing process to remove a part of the etch stop layer right above the dummy gate and the dummy gate.

14. The method of forming a gate according to claim 13, wherein the removing process comprises a first removing process and a second removing process.

15. The method of forming a gate according to claim 14, wherein the first removing process is performed to remove the part of the etch stop layer right above the dummy gate and a top part of the dummy gate.

16. The method of forming a gate according to claim 15, wherein the second removing process is performed to remove a remaining part of the dummy gate, thereby forming a recess in the dielectric layer.

17. The method of forming a gate according to claim 16, further comprising:
forming a metal gate in the recess.

18. The method of forming a gate according to claim 7, wherein a height of the oxide layer is larger than heights of the voids of the planarized top surface of the dielectric layer.
